(19) United States
(12) Patent Application Publication
(10) Pub. No.: US 2010/0026397 A1
(43) Pub. Date: Feb. 4, 2010

(54) PLL CIRCUIT

(75) Inventor: Katsuki Matsudera, Kanagawa (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/494,579

(22) Filed: Jun. 30, 2009

(30) Foreign Application Priority Data
Aug. 4, 2008 (JP) 2008-200487

(51) Int. Cl. H03L 7/00

(52) U.S. Cl. 331/34

(57) ABSTRACT

A PLL circuit includes a VCO circuit that generates an output clock having a frequency corresponding to potential of a first control voltage signal input from an LPF at a pre-stage, using a ring oscillator in which M delay circuits having delay times changing according to a control voltage input to a control terminal are connected in a ring shape. The VCO circuit includes a low-pass filter that extracts a second control voltage signal in a low frequency band from the first control voltage signal, and, in the ring oscillator. The first control voltage signal is input to control terminals of m (m<M) delay circuits among the M delay circuits and the second control voltage signal is input to control terminals of (M−m) delay circuits.

### CROSS-REFERENCE TO RELATED APPLICATIONS

This application is based upon and claims the benefit of priority from the prior Japanese Patent Application No. 2008-200487, filed on Aug. 4, 2008; the entire contents of which are incorporated herein by reference.

### BACKGROUND OF THE INVENTION

1. Field of the Invention

The present invention relates to a phase locked loop (PLL) circuit.

2. Description of the Related Art

In a PLL circuit, a voltage-controlled oscillation circuit (VCO circuit) outputs a clock of a desired frequency based on a control voltage signal from a low-pass filter at a pre-stage. An oscillation frequency range of the VCO circuit is proportional to a VCO gain (an oscillation frequency change ratio of the VCO circuit vs a voltage change ratio of the control voltage signal). When the VCO gain is large, the oscillation frequency range is large and, when the VCO gain is small, the oscillation frequency range is small.

In the PLL circuit, when noise occurs in the control voltage signal from the low-pass filter at the pre-stage, jitter appears in an output clock. When noise occurs in the control voltage signal, noise also rides on the oscillation frequency of the VCO circuit in proportion to the VCO gain. Therefore, when the VCO gain is large, the jitter of the output clock is large and, when the VCO gain is small, the jitter is small.

In an apparatus in which an output clock of a PLL circuit is used for a clock of an internal circuit, when the internal circuit is actuated at high speed and high accuracy, jitter needs to be small in the output clock of the PLL circuit. Therefore, conventionally, a technology for reducing jitter of an output clock while maintaining a wide oscillation frequency range of a VCO circuit is proposed (see, for example, JP-A H9-270704 (KOKAI) and JP-A 2003-168975 (KOKAI)).

JP-A H9-270704 (KOKAI) discloses a phase-locked circuit in which a circuit (having a large VCO gain) for roughly adjusting an oscillation frequency of a VCO circuit and a circuit (having a small VCO gain) for finely adjusting the oscillation frequency are provided. First, the phase-locked circuit adjusts an oscillation frequency to a certain degree through the rough adjustment and, then, finely adjusts the oscillation frequency through the fine adjustment. However, the PLL circuit is complicated and it is troublesome to set and control a frequency range in the fine adjustment.

JP-A 2003-168975 (KOKAI) discloses a PLL circuit including, as a VCO circuit, a two-control input type VCO circuit having a frequency rough adjustment control terminal with high gain and a frequency fine adjustment control terminal with low gain. The PLL circuit sets a VCO gain high in a low frequency band and sets the VCO gain low in a high frequency band. However, in this configuration, a circuit for increasing a DC gain of the VCO circuit is necessary. Therefore, as in JP-A H9-270704 (KOKAI), the PLL circuit is complicated.

### BRIEF SUMMARY OF THE INVENTION

According to one aspect of the present invention, a PLL circuit includes a phase-frequency comparing circuit that outputs a phase frequency difference signal having pulse width corresponding to a phase frequency difference between a reference clock and a feedback clock generated from an output clock; a charge pump circuit that supplies an electric current corresponding to the pulse width of the phase frequency difference signal; a first low-pass filter that converts an electric current from the charge pump circuit into a first control voltage signal; and a voltage-controlled oscillation circuit that generates the output clock having a frequency corresponding to potential of the first control voltage signal input from the first low-pass filter, using a ring oscillator in which M delay circuits having delay times changing according to a control voltage input to a control terminal are connected in a ring shape, wherein the voltage-controlled oscillation circuit includes a second low-pass filter that extracts a second control voltage signal in a low frequency band from the first control voltage signal, and the first control voltage signal is input to the control terminals of m (m<M) delay circuits among the M delay circuits and the second control voltage signal is input to the control terminals of (M−m) delay circuits, in the ring oscillator.

According to another aspect of the present invention, a PLL circuit includes a phase-frequency comparing circuit that outputs a phase frequency difference signal having pulse width corresponding to a phase frequency difference between a reference clock and a feedback clock generated from an output clock; a charge pump circuit that supplies an electric current corresponding to the pulse width of the phase frequency difference signal; a first low-pass filter that converts an electric current from the charge pump circuit into a first control voltage signal; and a voltage-controlled oscillation circuit that generates the output clock having a frequency corresponding to potential of the first control voltage signal input from the first low-pass filter, using a ring oscillator in which M delay circuits having delay times changing according to a control voltage input to a control terminal are connected in a ring shape, wherein the first low-pass filter outputs, besides the first control voltage signal, a second control voltage signal in a frequency band lower than the first control voltage signal to the voltage-controlled oscillation circuit, and the first control voltage signal is input to the control terminals of m (m<M) delay circuits among the M delay circuits and the second control voltage signal is input to the control terminals of (M−m) delay circuits, in the ring oscillator.

According to still another aspect of the present invention, a PLL circuit includes a phase-frequency comparing circuit that outputs a phase frequency difference signal having pulse width corresponding to a phase frequency difference between a reference clock and a feedback clock generated from an output clock; a charge pump circuit that supplies an electric current corresponding to the pulse width of the phase frequency difference signal; a first low-pass filter that converts an electric current from the charge pump circuit into a first control voltage signal; and a voltage-controlled oscillation circuit that generates the output clock having a frequency corresponding to potential of the first control voltage signal input from the first low-pass filter, using an LC resonator including an inductor and a variable capacitance element having a capacitance value changing according to an input control voltage, wherein the first low-pass filter outputs, besides the first control voltage signal, a second control voltage signal in a frequency band lower than the first control voltage signal to the voltage-controlled oscillation circuit, and the variable capacitance element includes a first variable capacitance element to which the first control voltage signal is input and a second variable capacitance element to which the second control voltage signal is input.

### BRIEF DESCRIPTION OF THE DRAWINGS

FIG. 1 is a block diagram of a configuration of a PLL circuit including a voltage-controlled oscillation circuit according to a first embodiment of the present invention;

FIG. 2 is a circuit diagram of an example of another configuration of an low-pass filter (LPF) shown in FIG. 1;

FIG. 3 is a circuit diagram of an example of a configuration of a VCO circuit shown in FIG. 1;

FIG. 4 is a characteristic chart for explaining an operation characteristic of the VCO circuit shown in FIG. 3;

FIG. 5 is a circuit diagram of a first example of a configuration of a ring oscillator shown in FIG. 3;

FIG. 6 is a circuit diagram of a second example of a configuration of the ring oscillator shown in FIG. 3;

FIG. 7 is a circuit diagram of a third example of a configuration of the ring oscillator shown in FIG. 3;

FIG. 8 is a block diagram of a configuration of a PLL circuit including a voltage-controlled oscillation circuit according to a second embodiment of the present invention;

FIG. 9 is a circuit diagram of an example of a configuration of a VCO circuit shown in FIG. 8;

FIG. 10 is a circuit diagram of a first example of another configuration of the voltage-controlled oscillation circuit in the PLL circuit shown in FIG. 8 (the second embodiment) as a third embodiment of the present invention;

FIG. 11 is a circuit diagram of a second example of another configuration of the voltage-controlled oscillation circuit in the PLL circuit shown in FIG. 8 (the second embodiment) as a fourth embodiment of the present invention; and

FIG. 12 is a circuit diagram of a third example of another configuration of the voltage-controlled oscillation circuit in the PLL circuit shown in FIG. 8 (the second embodiment) as a fifth embodiment of the present invention.

### DETAILED DESCRIPTION OF THE INVENTION

Exemplary embodiments of the PLL circuit according to the present invention will be explained in detail below with reference to the accompanying drawings. The present invention is not limited to the following embodiments.

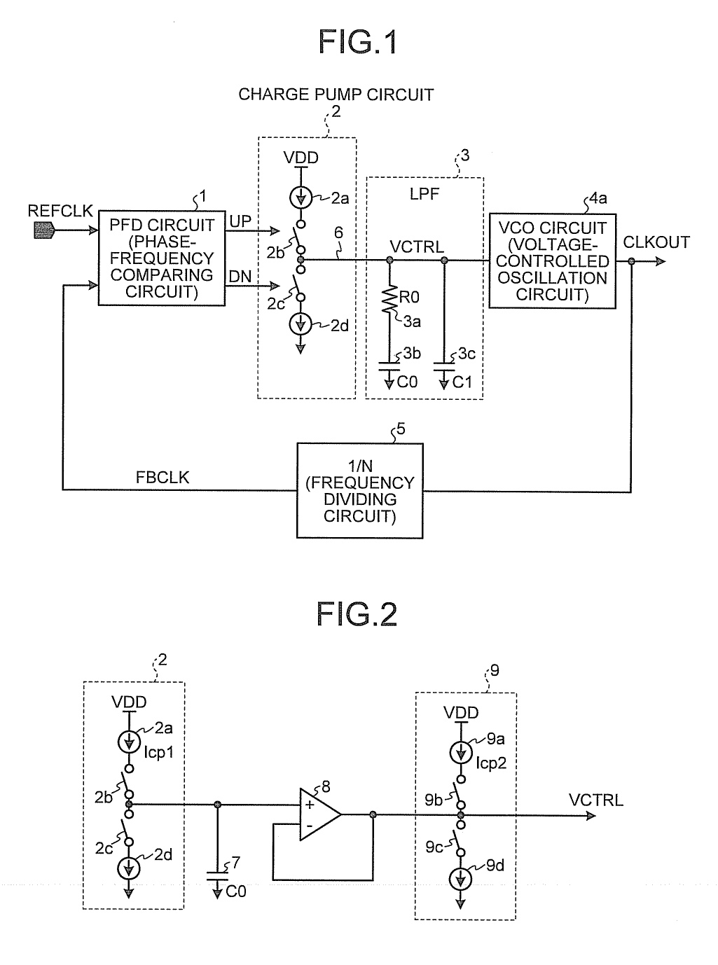

FIG. 1 is a block diagram of a configuration of a phase locked loop (PLL) circuit including a voltage-controlled oscillation circuit according to a first embodiment of the present invention. As shown in FIG. 1, like the general PLL circuit, the PLL circuit according to the first embodiment includes, as basic components, a phase-frequency comparing circuit (a PFD circuit) 1, a charge pump circuit 2, a low-pass filter (LPF) 3 for phase compensation for stability of a feedback loop, a voltage-controlled oscillation circuit (a VCO circuit) 4a, and a frequency dividing circuit 5.

### [General Configuration and Operation of the PLL Circuit]

A reference clock REFCLK is input to one input terminal of the PFD circuit 1 from the outside. A feedback clock FBCLK is input to the other input terminal from the frequency dividing circuit 5. The feedback clock FBCLK is a clock signal obtained by dividing an output clock CLKOUT generated by the VCO circuit 4a by N.

The PFD circuit 1 compares phases and frequencies of the reference clock REFCLK and the feedback flock FBCLK. The PFD circuit 1 outputs an up signal UP to the charge pump circuit 2 when, as a result of the comparison, the phase of the reference clock REFCLK advances and when the frequency of the reference clock REFCLK is high. Conversely, the PFD circuit 1 outputs a down signal DN to the charge pump circuit 2 when the phase of the reference clock REFCLK delays and when the frequency of the reference clock REFCLK is low. The PFD circuit 1 activates the up signal UP and the down signal DN for time proportional to a detected phase difference and a detected frequency difference.

In the charge pump circuit 2, a current source 2a, switches 2b and 2c, and a current source 2d are arranged in series in this order from a circuit power supply VDD side between the circuit power supply VDD and a circuit ground. The switch 2b performs opening and closing operation according to presence or absence of input of the up signal UP from the PFD circuit 1. The switch 2c performs opening and closing operation according to presence or absence of input of the down signal DN from the PFD circuit 1. A connection end of the switches 2b and 2c is connected to a control input terminal of the VCO circuit 4a via a connection line 6 that passes through an LPF 3.

In the LPF 3, a series circuit including a resistive element (having a resistance value R0) 3a and a capacitive element (having a capacitance value C0) 3b and a capacitive element (having a capacitance value C1) 3c are arranged in parallel between the connection line 6 and the circuit ground. A magnitude relation of the capacitance values between the capacitive elements 3b and 3c is C0>C1. The capacitive element 3c is provided for the purpose of removing a switching noise component. In some case, the capacitive element 3c is not used.

In the configuration of the charge pump circuit 2 and the LPF 3 explained above, when the switch 2b of the charge pump circuit 2 performs closing operation for a period in which the up signal UP is active, the capacitive elements 3b and 3c of the LPF 3 are charged by the current source 2a and the potential of the connection line 6 rises. Conversely, when the switch 2c of the charge pump circuit 2 performs closing operation for a period in which the down signal DN is active, charges charged in the capacitive elements 3b and 3c of the LPF 3 are discharged to the circuit ground through the current source 2d and the potential of the connection line 6 falls. A high frequency component included in a voltage signal appearing in the connection line 6 is removed by the LPF 3 (the series circuit of the resistive element 3a and the capacitive element 3b) and input to the control input terminal of the VCO circuit 4a as a control voltage signal VCTRL.

When the LPF 3 includes only the series circuit of the resistive element 3a and the capacitive element 3b, the control voltage signal VCTRL is represented by Formula (1) below. In Formula (1), Icp represents a current value of the current sources 2a and 2d in the charge pump circuit 2.

$$VCTRL = \frac{\int Icp ( t ) d t}{{C}_{0}} + Icp ( t ) \cdot {R}_{0} \qquad ( 1 )$$

FIG. 2 is a circuit diagram of an example of another configuration of the LPF 3 shown in FIG. 1. An LPF interposed between the charge pump circuit 2 and the VCO circuit 4a may include a capacitive element (having a capacitance value CO) 7, an operational (OP) amplifier 8, and a charge pump circuit 9, for example, as shown in FIG. 2. Like the charge pump circuit 2, in the charge pump circuit 9, a current source 9a, switches 9b and 9c, and a current source 9d are arranged in series in this order from the circuit power supply VDD side between the circuit power supply VDD and the circuit ground. The switch 9b performs opening and closing operation according to presence or absence of input of the up signal UP from the PFD circuit 1. The switch 9c performs opening and closing operation according to presence or absence of input of the down signal DN from the PFD circuit 1. The charge pump circuit 9 is different from the charge pump circuit 2 in a current value. In FIG. 2, a current value of the current sources 2a and 2d in the charge pump circuit 2 is represented as Icp1 and a current value of the current sources 9a and 9d in the charge pump circuit 9 is represented as Icp2.

A non-inverting input terminal (+) of the OP amplifier 8 is connected to the connection end of the switches 2b and 2c of the charge pump circuit 2. A capacitive element 7 (having a capacitance value C0) is connected between the non-inverting input terminal (+) of the OP amplifier 8 and the circuit ground. An inverting input terminal (−) of the OP amplifier 8 is connected to an output terminal. The output terminal of the OP amplifier 8 is connected to the control input terminal of the VCO circuit 4a via a connection end of the switches 9b and 9c of the charge pump circuit 9. The OP amplifier 8 of this voltage follower configuration realizes the function of the resistive element 3a in the LPF 3 shown in FIG. 1. Therefore, when a gain of the OP amplifier 8 is represented as gm, the control voltage signal VCTRL given to the VCO circuit 4a by the LPF shown in FIG. 2 is represented by the following Formula (2):

$$VCTRL = \frac{\int Icp 1 ( t ) d t}{{C}_{0}} + \frac{Icp 2 ( t )}{gm} \qquad ( 2 )$$

The VCO circuit 4a is a VCO circuit according to the first embodiment. However, basic operation thereof is the same as that in a conventional technology. When the potential of the control voltage signal VCTRL from the LPF 3 is high, the VCO circuit 4a oscillates at a high frequency. When the potential of the control voltage signal VCTRL is low, the VCO circuit 4a oscillates at a low frequency.

The output clock CLKOUT of a certain frequency generated by the VCO circuit 4a according to the potential of the control voltage signal VCTRL in this way is divided by N in the frequency dividing circuit 5 and given to the PFD circuit 1 as the feedback clock FBCLK. According to this feedback loop, the control voltage signal VCTRL of a moderate voltage value is input to the VCO circuit 4a and the VCO circuit 4a outputs the clock CLKOUT of a desired frequency. As a result of comparison of phases and frequencies between the reference clock REFCLK and the feedback clock FBCLK in the PFD circuit 1, the output clock CLKOUT at lock time when the phases and the frequencies are stably the same has a substantially fixed frequency (N times as large as that of the reference clock REFCLK).

### Configuration of the VCO Circuit 4a according to the First Embodiment

The VCO circuit 4a according to this embodiment is a ring oscillator type in which a plurality of delay circuits are connected in a ring shape. The delay circuits include CMOS inverter circuits or differential pair MOS transistors. In both the cases, the delay circuits have control terminals to which a control voltage for designating delay time is input. As a configuration of internal circuits, there are a type that operates directly in response to the control voltage input to the control terminals (a voltage dependent type) and a type that operates by converting the control voltage input to the control terminals into an electric current (a current dependent type).

One of characteristic differences between the ring oscillator including the CMOS inverter circuits and the ring oscillator including the differential pair MOS transistors is that the number of connections is only an odd number in the former ring oscillator but the number of connections is an odd number or an even number in the latter ring oscillator. In the first embodiment, the ring oscillator including the CMOS inverter circuits having a simple configuration, explanation of which is simple, is explained as an example. Naturally, the explanation can also be applied to the ring oscillator including the differential pair MOS transistors.

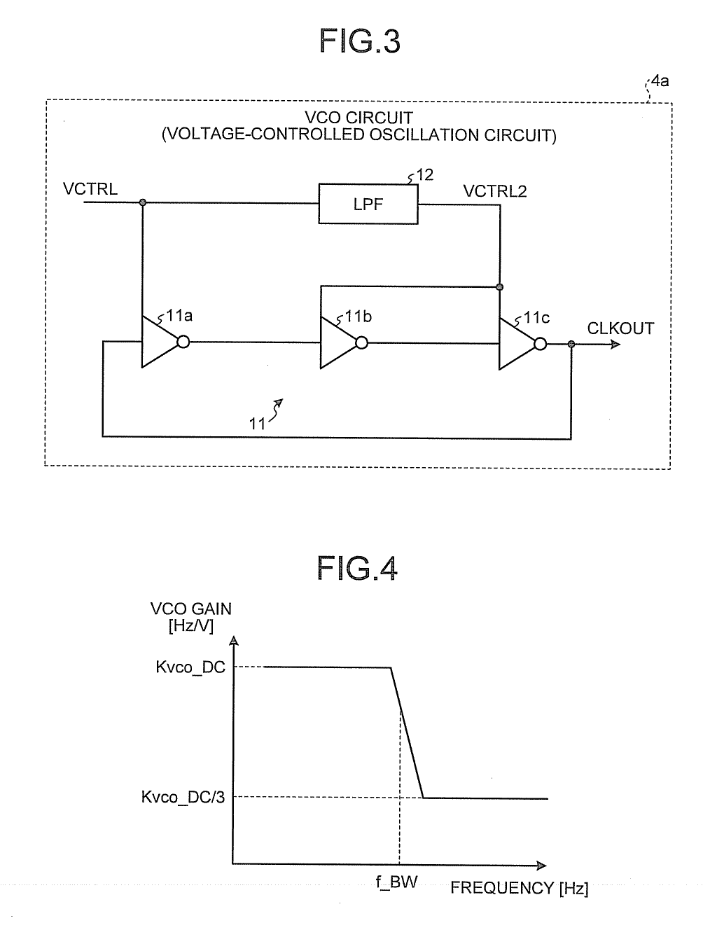

FIG. 3 is a circuit diagram of an example of a configuration of the VCO circuit 4a shown in FIG. 1. As shown in FIG. 3, the VCO circuit 4a shown in FIG. 1 includes a ring oscillator 11 including CMOS inverter circuits and an LPF 12. The VCO circuit 4a is configured by adding the LPF 12 to a VCO circuit of a general ring oscillator configuration.

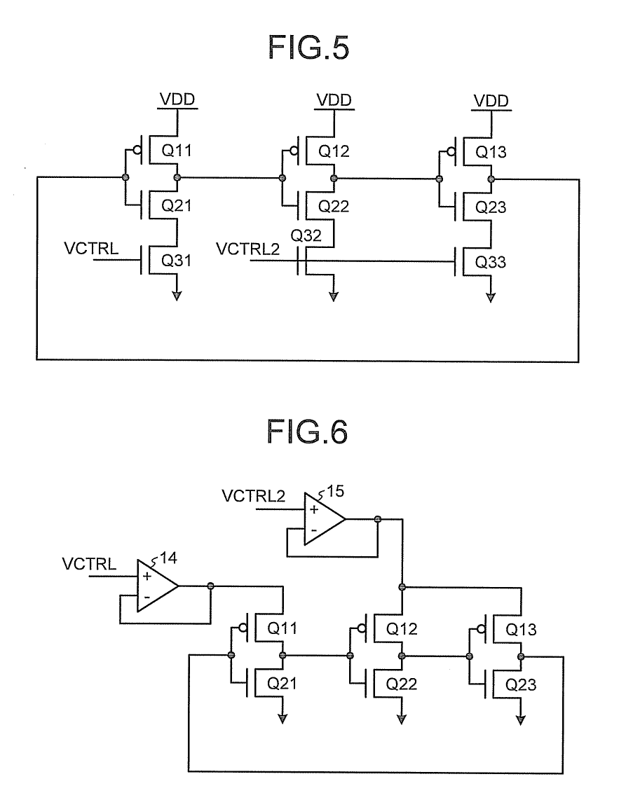

In the ring oscillator 11, for example, three delay circuits 11a, 11b, and 11c are connected in a ring shape. In each of the delay circuits 11a, 11b, an 11c, when an input voltage value to control terminals or a current value corresponding to the input voltage value is high, delay time is large, and when the input voltage value or the current value is low, the delay time is small. The LPF 12 extracts a control voltage signal VCTRL2 in a low frequency band from the control voltage signal VCTRL and outputs the control voltage signal VCTRL2. A specific example of a configuration of the ring oscillator 1 is explained later (FIGS. 5 to 7).

In FIG. 3, as a relation between the ring oscillator 11 and the LPF 12, the control voltage signal VCTRL input from the LPF 3 to the LPF 12 is input to a control terminal of the first stage delay circuit 11a to which the output clock CLKOUT is input. The output VCTRL2 of the LPF 12 is input in common to control terminals of the intermediate stage delay circuit 11b and the last stage delay circuit 11c that outputs the output clock CLKOUT. However, this is only an example. The control voltage signal VCTRL can be input in common to the control terminals of the delay circuits 11a and 11b and the output VCTRL2 of the LPF 12 can be input to the control terminal of the delay circuit 11c.

In the VCO circuit of the general ring oscillator configuration, the control voltage signal VCTRL is given in common to the control terminals of all the delay circuits such that delay time is the same in the delay circuits. However, in the first embodiment, the control voltage signal VCTRL is given to a part of all the delay circuits and the control voltage signal VCTRL2 is given to the remaining delay circuits such that delay time can be changed according to a band of a frequency component included in the control voltage signal VCTRL. Consequently, in the VCO circuit 4a, an oscillation frequency by a DC component of the control voltage signal VCTRL input from the LPF 3 can be changed according to the band of the frequency component included in the control voltage signal VCTRL. Therefore, an AC gain of VCO can be easily adjusted.

### Operation of the VCO Circuit 4a according to the First Embodiment

FIG. 4 is a characteristic chart for explaining an operation characteristic of the VCO circuit 4a shown in FIG. 3. In FIG. 4, the ordinate represents a VCO gain Kvco (Hz/V). Kvco_DC and Kvco_DC/3, which is one third of Kvco_DC, are shown on the ordinate. The abscissa represents a frequency component (Hz) included in the control voltage signal VCTRL. A band f_BW of the LPF 12 is shown on the abscissa.

As shown in FIG. 4, the VCO gain obtained when the frequency component included in the control voltage signal VCTRL changes at a frequency lower than the band f_BW of the LPF 12 is Kvco_DC. The Kvco_DC is a VCO gain obtained in the VCO circuit of the general ring oscillator configuration.

The VCO gain obtained when the frequency component included in the control voltage signal VCTRL changes at a frequency higher than the band f_BW of the LPF 12 is Kvco_DC/3 in the configuration shown in FIG. 3. The VCO gain in the configuration for inputting the voltage signal VCTRL in common to the control terminals of the delay circuits 11a and 11b and inputting the output VCTRL2 of the LPF 12 to the control terminal of the delay circuit 11c as explained above is ⅔ of Kvco_DC. The characteristic for reducing the VCO gain in the high frequency band in this way is a characteristic that is not obtained in the VCO circuit of the general ring oscillator configuration.

Therefore, in the VCO circuit 4a, even if noise rides on the control voltage signal VCTRL, a VCO gain is small on a frequency side higher than a band of the added LPF 12. Therefore, jitter of a high frequency appearing in the output clock CLKOUT can be reduced.

When the noise riding on the control voltage signal VCTRL is in a frequency domain lower than a loop band of the PLL circuit, a feedback control system of the PLL circuit can follow the frequency domain. Therefore, jitter of the output clock CLKOUT by the noise riding on the control voltage signal VCTRL is suppressed. In these cases, the VCO gain in the low frequency domain is as high as that obtained in the VCO circuit of the general ring oscillator configuration. Therefore, an oscillation frequency range is kept wide in the VCO circuit 4a.

In the VCO circuit 4a explained with reference to FIG. 3, the ring oscillator of the three stage configuration is used. However, as it is understood from the above explanation, if a ring oscillator of N stages larger than the three stages is used, a VCO gain on a high frequency side exceeding the band of the LPF 12 can be set in a range of 1/N to (N−1)/N. When it is taken into account that the delay circuit includes the differential pair MOS transistors, the value N is a positive integer including an even number.

### [Configuration Examples of the Ring Oscillator 11]

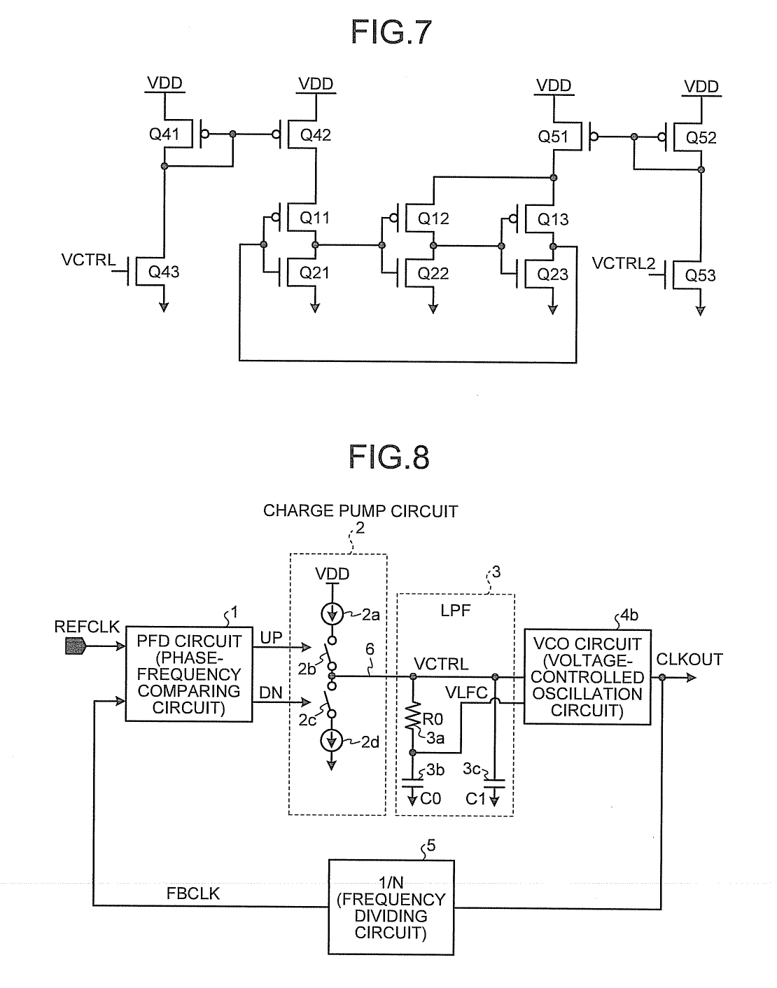

FIGS. 5 to 7 are circuit diagrams of first to third examples of configurations of the ring oscillator 11 shown in FIG. 3. FIGS. 5 and 6 are circuit diagrams of the ring oscillator 11 of a voltage dependent type. FIG. 7 is a circuit diagram of the ring oscillator 11 of a current dependent type.

In FIG. 5, one end sides of three CMOS inverter circuits (Q11, Q21), (Q12, Q22), and (Q13, Q23) connected in a ring shape are connected to the circuit power supply VDD. The other end sides thereof are connected to the circuit ground via NMOS transistors Q31, Q32, and Q33. In this configuration, gate terminals of the NMOS transistors Q31, Q32, and Q33 are control terminals to which control voltage is input.

The control voltage signal VCTRL from the LPF 3 is input to the gate terminal of the NMOS transistor Q31 corresponding to the CMOS inverter circuit (Q11, Q21). The control voltage signal VCTRL2 from the LPF 12 is input to the gate terminals of the NMOS transistors Q32 and Q33 corresponding to the CMOS inverter circuit (Q12, Q22) and (Q13, Q23).

In the ring oscillator shown in FIG. 5, a drain current that flows when the NMOS transistor Q21 of the CMOS inverter circuit (Q11, Q21) is turned on changes according to a voltage value of the control voltage signal VCTRL from the LPF 3. A drain current that flows when the NMOS transistors Q22 and Q23 of the CMOS inverter circuits (Q12, Q22) and (Q13, Q23) are turned on changes according to a voltage value of the control voltage signal VCTRL2 from the LPF 12. Consequently, delay times of the CMOS inverter circuit (Q11, Q21) and the CMOS inverter circuits (Q12, Q22) and (Q13, Q23) are changed to increase or decrease.

However, in the ring oscillator shown in FIG. 5, the potentials of the control voltage signals VCTRL and VCTRL2 are affected by switching operation of the CMOS inverter circuits (Q11, Q21), (Q12, Q22), and (Q13, Q23) and fluctuate. The ring oscillator shown in FIG. 6 suppresses this fluctuation in potentials of the control voltage signals VCTRL and VCTRL2.

In FIG. 6, the control voltage signal VCTRL is input to one end side of the CMOS inverter circuit (Q11, Q21) via an OP amplifier 14 of a voltage follower configuration. The control voltage signal VCTRL2 is input in common to one end sides of the CMOS inverter circuits (Q12, Q22) and (Q13, Q23) via an OP amplifier 15 of a voltage follower configuration. The other ends of the CMOS inverter circuits (Q11, Q21), (Q12, Q22), and (Q13, Q23) are directly connected in common to the circuit ground. The OP amplifiers 14 and 15 of the voltage follower configuration are regulators for voltage-to-voltage conversion. In this configuration, non-inverting input terminals (+) of the OP amplifiers 14 and 15 are control terminals to which the control voltage is input.

In a ring oscillator shown in FIG. 7, instead of the OP amplifiers 14 and 15 shown in FIG. 6, current mirror circuits (Q41, Q42) and (Q51, Q52), one end sides of which are connected to the circuit power supply VDD, and NMOS transistors Q4 and Q53 that configure control terminals are provided.

In the current mirror circuit (Q41, Q42), a drain terminal of a PMOS transistor Q42 on the other end side is connected to one end side of the CMOS inverter circuit (Q11, Q21). The control voltage signal VCTRL is input to a gate terminal of an NMOS transistor Q43 arranged between a drain terminal of a diode-connected PMOS transistor Q41 on the same other end side and the circuit ground. Consequently, a mirror current corresponding to a voltage value of the control voltage signal VCTRL is supplied from the drain terminal of the PMOS transistor Q42 to one end side of the CMOS inverter circuit (Q11, Q21). Delay time of the CMOS inverter circuit (Q11, Q21) is changed to increase or decrease according to a mirror current value.

In the current mirror circuit (Q51, Q52), a drain terminal of a PMOS transistor Q51 on the other end side is connected to the one end sides of the CMOS inverter circuits (Q12, Q22) and (Q13, Q23). The control voltage signal VCTRL2 is input to a gate terminal of an NMOS transistor Q53 arranged between a drain terminal of a diode-connected PMOS transistor Q52 on the same other end and the circuit ground. Consequently, a mirror current corresponding to a voltage value of the control voltage signal VCTRL2 is supplied from the drain terminal of the PMOS transistor Q51 to the one end sides of the CMOS inverter circuits (Q12, Q22) and (Q13, Q23). Delay times of the CMOS inverter circuits (Q12, Q22) and (Q13, Q23) are changed to increase or decrease according to a mirror current value.

As explained above, according to the first embodiment, it is possible to obtain a PLL circuit that can reduce, with a simple circuit configuration and without requiring complicated control, jitter of an output clock while maintaining a wide oscillation frequency range of a VCO circuit.

FIG. 8 is a block diagram of a configuration of a PLL circuit including a voltage-controlled oscillation circuit according to a second embodiment of the present invention. In FIG. 8, components same as or equivalent to the components shown in FIG. 1 (the first embodiment) are denoted by the same reference numerals and signs. Components related to the second embodiment are mainly explained below.

As shown in FIG. 8, in the PLL circuit according to the second embodiment, a VCO circuit 4b is provided instead of the VCO circuit 4a in the configuration shown in FIG. 1 (the first embodiment). Besides the control voltage signal VCTRL, potential appearing at a connection end of the resistive element 3a and the capacitive element 3b that configure the LPF 3 is input to the VCO circuit 4b from the LPF 3 as a control voltage signal VLFC.

A band of a frequency component included in the control voltage signal VLFC is a band lower than the band of the frequency component included in the control voltage signal VCTRL. When the LPF 3 has the configuration shown in FIG. 2, the control voltage signal VLFC is extracted from a line that connects the non-inverting input terminal (+) of the OP amplifier 8 and the connection end of the switches 2b and 2c of the charge pump circuit 2.

Configuration of the VCO Circuit 4b according to the Second Embodiment

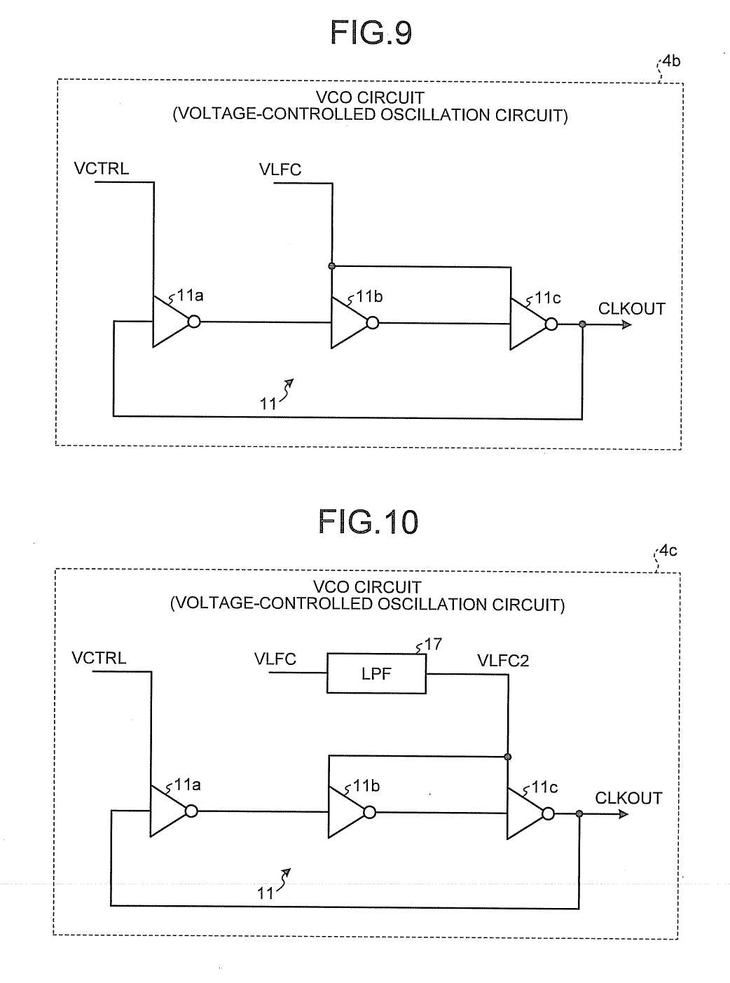

FIG. 9 is a circuit diagram of an example of a configuration of the VCO circuit 4b shown in FIG. 8. As shown in FIG. 9, the VCO circuit 4b includes, for example, the ring oscillator 11 shown in FIG. 3. The control voltage signal VCTRL is input to the control terminal of the first stage delay circuit 11a to which the output clock CLKOUT is input. The control voltage signal VLFC is input in common to the control terminals of the intermediate stage delay circuit 11b and the last stage delay circuit 11c that outputs the output clock CLKOUT. However, this is only an example. The control voltage signal VCTRL can be input in common to the control terminals of the delay circuits 11a and 11b. The control voltage signal VLFC can be input to the control terminal of the delay circuit 11c.

The ring oscillators having the configurations shown in FIGS. 5 to 7 can also be used as the ring oscillator 11 that configures the VCO circuit 4b by changing the VCTRL2 to VLFC.

### Operation of the VCO Circuit 4b according to the Second Embodiment

A frequency band of the control voltage signal VLFC is a band lower than the frequency band of the control voltage signal VCTRL. Therefore, a VCO gain of the VCO circuit 4b has a characteristic same as that of the VCO circuit 4a. A VCO gain obtained when the frequency component included in the control voltage signal VCTRL changes at a frequency lower than the frequency band of the control voltage signal VLFC is Kvco_DC.

A VCO gain obtained when the frequency component included in the control voltage signal VCTRL changes at a frequency higher than the frequency band of the control voltage signal VLFC is Kvco_DC/3 in the configuration shown in FIG. 9. As explained above, a VCO gain in the configuration for inputting the control voltage signal VCTRL in common to the control terminals of the delay circuits 11a and 11b and inputting the control voltage signal VLFC to the control terminal of the delay circuit 11c is ⅔ of Kvco_DC.

Therefore, in the VCO circuit 4b, even if noise rides on the control voltage signal VCTRL, a VCO gain is small on a frequency side higher than the frequency band of the control voltage signal VLFC. Therefore, jitter of a high frequency appearing in the output clock CLKOUT can be reduced.

As explained above, according to the second embodiment, it is possible to obtain actions and effects same as those in the first embodiment. In addition, because a VCO circuit can be configured by only a ring oscillator, it is possible to further realize simplification of the VCO circuit than that in the first embodiment.

FIG. 10 is a circuit diagram of a first example of another configuration of the voltage-controlled oscillation circuit in the PLL circuit shown in FIG. 8 (the second embodiment) as a third embodiment of the present invention.

As shown in FIG. 10, in a voltage-controlled oscillation circuit (VCO) 4c according to the third embodiment, an LPF 17 is provided in a path for inputting the control voltage signal VLFC to the control terminals of the delay circuits 11b and 11c in the VCO circuit 4b shown in FIG. 9. The LPF 17 extracts a control voltage signal VLFC2 in a low band from the control voltage signal VLFC and outputs the control voltage signal VLFC2 to the control terminals of the delay circuits 11b and 11c.

With the configuration shown in FIG. 10, a band of a frequency component included in the control voltage signal VLFC2 can be set lower than the band of the frequency component included in the control voltage signal VLFC from the LPF 3. Therefore, in the VCO circuit 4c, a frequency band for reducing a VCO gain to ⅓ can be set further on a low frequency side than that in the second embodiment.

According to the third embodiment, it is possible to effectively use a noise suppressing function by a feedback system of a PLL circuit by setting the frequency band for reducing the VCO gain to ⅓ in a domain lower than loop band width of the PLL circuit.

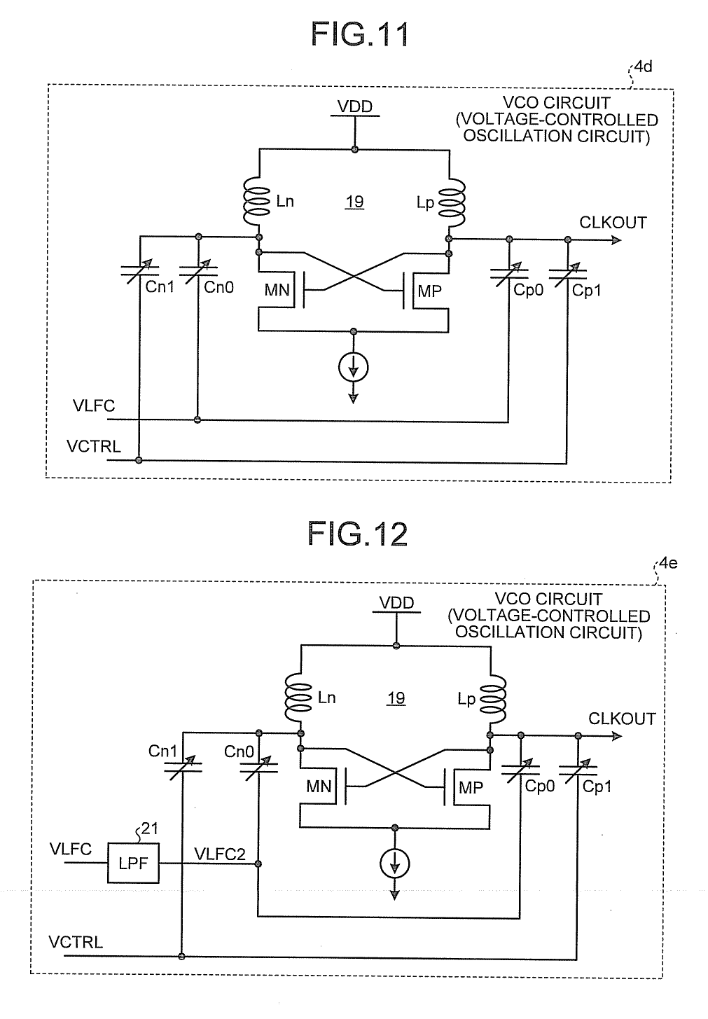

FIG. 11 is a circuit diagram of a second example of another configuration of the voltage-controlled oscillation circuit in the PLL circuit shown in FIG. 8 (the second embodiment) as a fourth embodiment of the present invention.

As shown in FIG. 11, a voltage-controlled oscillation circuit (VCO) 4d according to the fourth embodiment of the present invention includes an LC resonator 19. The LC resonator 19 includes varactors Cn0, Cn1, Cp0, and Cp1 as voltage dependent capacitive elements and MOS transistors MN and MP. Gate terminals and drain terminals of the MOS transistors MN and MP are connected to intersect each other.

In the example shown in FIG. 11, one end sides of inductors Ln and Lp are connected to the circuit power supply VDD. Drain terminals of the MOS transistors MN and MP are connected to the other end sides of the inductors Ln and Lp. Source terminals of the MOS transistors MN and MP are connected to the circuit ground via a current source. One end sides of the varactors Cn0 and Cn1 are connected to a connection end of the other end side of the inductor Ln and the MOS transistor MN. One end sides of the varactors Cp0 and Cp1 are connected to a connection end of the other end side of the inductor Lp and the MOS transistor MP.

The inductors Ln and Lp and the varactors Cn0, Cn1, Cp0, and Cp1 configure an LC tank circuit. When capacitance values of the varactors Cn0, Cn1, Cp0, and Cp1 change and an impedance value of the LC tank circuit changes according to a control voltage signal input to the other end sides of the varactors Cn0, Cn1, Cp0, and Cp1, the inductors Ln and Lp and the varactors Cn0, Cn1, Cp0, and Cp1 change an oscillation frequency. The MOS transistors MN and MP connected to intersect each other function as negative resistance elements that cancel resistance losses that occur in the inductors Ln and Lp.

In a general LC resonator, one varactor is provided for the inductor Ln and one varactor is provided for the inductor Lp. A common control voltage signal is input to the varactors. When two varactors are provided for the inductor Ln and two varactors are provided for the inductor Lp, a common control voltage signal is input to the varactors of one inductor. The varactors of the other inductor are connected to the circuit ground.

In the fourth embodiment, as shown in FIG. 11, the control voltage signal VLFC is input to the other end sides of the varactors Cn0 and Cp0. The control voltage signal VCTRL is input to the other end sides of the varactors Cn1 and Cp1. An oscillation frequency of the LC resonator 19 changes according to the potential of the control voltage signal VCTRL and the potential of the control voltage signal VLFC. The varactors Cn1 and Cp1 correspond to a first variable capacitance element and the varactors Cn0 and Cp0 correspond to a second variable capacitance element.

When the same control voltage signal is input to the other end sides of the varactors Cn0, Cn1, Cp0, and Cp1, capacitance values of the varactors Cn0 and Cp0 are equally represented as C_dc and capacitance values of the varactors cn1 and Cp1 are equally represented as mxC_dc. “m” is a positive integer. A VCO gain of the VCO circuit 4d obtained when the control voltage signal VCTRL is input in common to the other end sides of the varactors Cn0, Cn1, Cp0, and Cp1 is represented as Kvco_DC2. Kvco_DC2 corresponds to Kvco_DC shown in FIG. 4.

As shown in FIG. 11, a VCO gain of the VCO circuit 4d actuated by inputting the control voltage signal VLFC to the other end sides of the varactors Cn0 and Cp0 and inputting the control voltage signal VCTRL to the other end sides of the varactors Cn1 and Cp1 is Kvco_DC2 when the frequency component included in the control voltage signal VCTRL changes at a frequency lower than the frequency band of the control voltage signal VLFC. The VCO gain is Kvco_DC2/(m+1) when the frequency component included in the control voltage signal VCTRL changes at a frequency higher than the frequency band of the control voltage signal VLFC.

As explained above, according to the fourth embodiment, when the LC resonator type VCO circuit is used, the original control voltage signal VCTRL and the control voltage signal VLFC in the frequency band lower than the control voltage signal VCTRL are input from the LPF at the pre-stage to change capacitance values of the varactors with the control voltage signals, respectively. Therefore, a VCO gain obtained when the control voltage signal VCTRL changes at a frequency higher than the frequency band of the control voltage signal VLFC can be reduced to m/(m+1). As in the first to third embodiments, it is possible to obtain a PLL circuit that can reduce jitter of an output clock.

FIG. 12 is a circuit diagram of a third example of another configuration of the voltage-controlled oscillation circuit in the PLL circuit shown in FIG. 8 (the second embodiment) as a fifth embodiment of the present invention.

As shown in FIG. 12, in a voltage-controlled oscillation circuit (VCO) 4e according to the fifth embodiment of the present invention, an LPF 21 is provided in a path for inputting the control voltage signal VLFC to the other end sides of the varactors Cn0 and Cp0 in the VCO circuit 4d shown in FIG. 11. The LPF 21 extracts the control voltage signal VLFC2 in the low frequency band from the control voltage signal VLFC and outputs the control voltage signal VLFC2 to the other end sides of the varactors Cn0 and Cp0.

With the configuration shown in FIG. 12, a band of a frequency component included in the control voltage signal VLFC2 can be set lower than the band of the frequency component included in the control voltage signal VLFC from the LPF 3. Therefore, in the VCO circuit 4e, a frequency band for reducing a VCO gain to m/(m+1) can be set further on a low frequency side than that in the second embodiment.

According to the fifth embodiment, as in the third embodiment, it is possible to effectively use a noise suppressing function by a feedback system of a PLL circuit by setting a frequency band for reducing an AC VCO gain in a domain lower than loop band width of the PLL circuit.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A PLL circuit comprising:
a phase-frequency comparing circuit that outputs a phase frequency difference signal having pulse width corresponding to a phase frequency difference between a reference clock and a feedback clock generated from an output clock;
a charge pump circuit that supplies an electric current corresponding to the pulse width of the phase frequency difference signal;
a first low-pass filter that converts an electric current from the charge pump circuit into a first control voltage signal; and
a voltage-controlled oscillation circuit that generates the output clock having a frequency corresponding to potential of the first control voltage signal input from the first low-pass filter, using a ring oscillator in which M delay circuits having delay times changing according to a control voltage input to a control terminal are connected in a ring shape, wherein
the voltage-controlled oscillation circuit includes a second low-pass filter that extracts a second control voltage signal in a low frequency band from the first control voltage signal, and
the first control voltage signal is input to the control terminals of m (m<M) delay circuits among the M delay circuits and the second control voltage signal is input to the control terminals of (M−m) delay circuits, in the ring oscillator.

2. The PLL circuit according to claim 1, wherein
the first low-pass filter includes
an operational amplifier of a voltage follower configuration, to a non-inverting input terminal of which an output terminal of the charge pump circuit is connected,
a capacitive element arranged between a first connection line for the output terminal of the charge pump circuit and the non-inverting input terminal and a circuit ground, and
a second charge pump circuit that supplies an electric current corresponding to the pulse width of the phase frequency difference signal to a second connection line for an output terminal of the operational amplifier and a control voltage input terminal of the voltage-controlled oscillation circuit, and
the first control voltage signal is voltage at the second connection line.

3. The PLL circuit according to claim 1, wherein the M delay circuits that configure the ring oscillator include M (M is an odd number) CMOS inverter circuits or M (M is an integer) differential pair MOS transistor circuits.

4. The PLL circuit according to claim 1, wherein
the ring oscillator includes
M (M is an odd number) CMOS inverter circuits connected in a ring shape with one ends thereof connected to a circuit power supply, and
M MOS transistors arranged between the respective other ends of the M CMOS inverter circuits and a circuit ground,
the first control voltage signal is input to gates of m (m<M) MOS transistors among the M MOS transistors, and
the second control voltage signal is input to gates of (M−m) MOS transistors.

5. The PLL circuits according to claim 1, wherein
the ring oscillator includes
a first operational amplifier of a voltage follower configuration, to a non-inverting input terminal of which the first control voltage signal is input,
a second operational amplifier of the voltage follower configuration, to a non-inverting input terminal of which the second control voltage signal is input, and
M (M is an odd number) CMOS inverter circuits connected in an ring shape with other ends thereof connected to a circuit ground,
one ends of M (m<M) CMOS inverter circuits among the M CMOS inverter circuits are connected to an output terminal
of the first operational amplifier, and one ends of (M−m) CMOS inverter circuits are connected to an output terminal of the second operational amplifier.

6. The PLL circuit according to claim 1, wherein
the ring oscillator includes
a first MOS transistor, to a gate of which the first control voltage signal is input and a source of which is connected to a circuit ground,
a first current mirror circuit that is arranged between a drain of the first MOS transistor and a circuit power supply and outputs a mirror current corresponding to a conduction state of the first MOS transistor,
a second MOS transistor, to a gate of which the second control voltage signal is input and a source of which is connected to the circuit ground,
a second current mirror circuit that is arranged between a drain of the second MOS transistor and a circuit power supply and outputs a mirror current corresponding to a conduction state of the second MOS transistor, and
M (M is an odd number) CMOS inverter circuits connected in a ring shape with other ends thereof connected to the circuit ground,
one ends of m (m<M) CMOS inverter circuits among the M CMOS inverter circuits are connected to an output terminal of the first current mirror circuit, and
one ends of (M−m) CMOS inverter circuits are connected to an output terminal of the second current mirror circuit.

7. A PLL circuit comprising:
a phase-frequency comparing circuit that outputs a phase frequency difference signal having pulse width corresponding to a phase frequency difference between a reference clock and a feedback clock generated from an output clock;
a charge pump circuit that supplies an electric current corresponding to the pulse width of the phase frequency difference signal;
a first low-pass filter that converts an electric current from the charge pump circuit into a first control voltage signal; and
a voltage-controlled oscillation circuit that generates the output clock having a frequency corresponding to potential of the first control voltage signal input from the first low-pass filter, using a ring oscillator in which M delay circuits having delay times changing according to a control voltage input to a control terminal are connected in a ring shape, wherein
the first low-pass filter outputs, besides the first control voltage signal, a second control voltage signal in a frequency band lower than the first control voltage signal to the voltage-controlled oscillation circuit, and
the first control voltage signal is input to the control terminals of m (m<M) delay circuits among the M delay circuits and the second control voltage signal is input to the control terminals of (M−m) delay circuits, in the ring oscillator.

8. The PLL circuit according to claim 7, wherein
the voltage-controlled oscillation circuit includes a second low-pass filter that extracts a third control voltage signal in a low frequency band from the second control voltage signal, and
the third control voltage signal, instead of the second control voltage signal, is input to the control terminals of the (M−m) delay circuits.

9. The PLL circuit according to claim 7, wherein
the first low-pass filter includes a series circuit including a resistive element and a capacitive element arranged between a connection line for an output terminal of the charge pump circuit and a control voltage input terminal of the voltage-controlled oscillation circuit and a circuit ground,
the first control voltage signal is voltage at both ends of the series circuit, and the second control voltage signal is extracted from a series connection end of the resistive element and the capacitive element.

10. The PLL circuit according to claim 7, wherein
the first low-pass filter includes
an operational amplifier of a voltage follower configuration, to a non-inverting input terminal of which an output terminal of the charge pump circuit is connected,
a capacitive element arranged between a first connection line for the output terminal of the charge pump circuit and the non-inverting input terminal and a circuit ground, and
a second charge pump circuit that supplies an electric current corresponding to the pulse width of the phase frequency difference signal to a second connection line for an output terminal of the operational amplifier and a control voltage input terminal of the voltage-controlled oscillation circuit,
the first control voltage signal is voltage at the second connection line, and
the second control voltage signal is extracted from the first connection line.

11. The PLL circuit according to claim 7, wherein the M delay circuits that configure the ring oscillator include M (M is an odd number) CMOS inverter circuits or M (M is an integer) differential pair MOS transistor circuits.

12. The PLL circuit according to claim 7, wherein
the ring oscillator includes
M (M is an odd number) CMOS inverter circuits connected in a ring shape with one ends thereof connected to a circuit power supply, and
M MOS transistors arranged between the respective other end of the M CMOS inverter circuits and a circuit ground,
the first control voltage signal is input to gates of m (m<M) MOS transistors among the M MOS transistors, and
the second control voltage signal is input to gates of (M−m) MOS transistors.

13. The PLL circuits according to claim 7, wherein
the ring oscillator includes
a first operational amplifier of a voltage follower configuration, to a non-inverting input terminal of which the first control voltage signal is input,
a second operational amplifier of the voltage follower configuration, to a non-inverting input terminal of which the second control voltage signal is input, and
M (M is an odd number) CMOS inverter circuits connected in an ring shape with other ends thereof connected to a circuit ground,
one ends of M (m<M) CMOS inverter circuits among the M CMOS inverter circuits are connected to an output terminal of the first operational amplifier, and
one ends of (M−m) CMOS inverter circuits are connected to an output terminal of the second operational amplifier.

14. The PLL circuit according to claim 7, wherein
the ring oscillator includes
a first MOS transistor, to a gate of which the first control voltage signal is input and a source of which is connected to a circuit ground,
a first current mirror circuit that is arranged between a drain of the first MOS transistor and a circuit power supply and outputs a mirror current corresponding to a conduction state of the first MOS transistor,
a second MOS transistor, to a gate of which the second control voltage signal is input and a source of which is connected to the circuit ground,
a second current mirror circuit that is arranged between a drain of the second MOS transistor and a circuit power supply and outputs a mirror current corresponding to a conduction state of the second MOS transistor, and
M (M is an odd number) CMOS inverter circuits connected in a ring shape with other ends thereof connected to the circuit ground,
one ends of m (m<M) CMOS inverter circuits among the M CMOS inverter circuits are connected to an output terminal of the first current mirror circuit, and
one ends of (M−m) CMOS inverter circuits are connected to an output terminal of the second current mirror circuit.

15. A PLL circuit comprising:
a phase-frequency comparing circuit that outputs a phase frequency difference signal having pulse width corresponding to a phase frequency difference between a reference clock and a feedback clock generated from an output clock;
a charge pump circuit that supplies an electric current corresponding to the pulse width of the phase frequency difference signal;
a first low-pass filter that converts an electric current from the charge pump circuit into a first control voltage signal; and
a voltage-controlled oscillation circuit that generates the output clock having a frequency corresponding to potential of the first control voltage signal input from the first low-pass filter, using an LC resonator including an inductor and a variable capacitance element having a capacitance value changing according to an input control voltage, wherein
the first low-pass filter outputs, besides the first control voltage signal, a second control voltage signal in a frequency band lower than the first control voltage signal to the voltage-controlled oscillation circuit, and
the variable capacitance element includes a first variable capacitance element to which the first control voltage signal is input and a second variable capacitance element to which the second control voltage signal is input.

16. The PLL circuit according to claim 15, wherein
the voltage-controlled oscillation circuit includes a second low-pass filter that extracts a third control voltage signal in a low frequency band from the second control voltage signal, and
the third control voltage signal, instead of the second control voltage signal, is input to the second variable capacitance element.

17. The PLL circuit according to claim 15, wherein
the first low-pass filter includes a series circuit including a resistive element and a capacitive element arranged between a connection line for an output terminal of the charge pump circuit and a control voltage input terminal of the voltage-controlled oscillation circuit and a circuit ground,
the first control voltage signal is voltage at both ends of the series circuit, and
the second control voltage signal is extracted from a series connection end of the resistive element and the capacitive element.

18. The PLL circuit according to claim 15, wherein
the first low-pass filter includes
an operational amplifier of a voltage follower configuration, to a non-inverting input terminal of which an output terminal of the charge pump circuit is connected, a capacitive element arranged between a first
connection line for the output terminal of the charge pump circuit and the non-inverting input terminal and a circuit ground, and
a second charge pump circuit that supplies an electric current corresponding to the pulse width of the phase frequency difference signal to a second connection line for an output terminal of the operational amplifier and a control voltage input terminal of the voltage-controlled oscillation circuit,
the first control voltage signal is voltage at the second connection line, and
the second control voltage signal is extracted from the first connection line.

19. The PLL circuit according to claim 15, wherein
the LC resonator includes
first and second MOS transistors, gates and drains of which are connected to intersect each other,
first and second inductors connected between the drains of the first and second MOS transistors and a circuit power supply,
a current source arranged between sources of the first and second MOS transistors and a circuit ground, and
two variable capacitance elements, one ends of which are connected to the drains of the first and second MOS transistors, respectively, and
each of the two variable capacitance elements includes
the first variable capacitance element, to other end of which the first control voltage signal is input, and
the second variable capacitance element, to other end of which the second control voltage signal is input.
